(19) United States
(12) Patent Application Publication
(10) Pub. No.: US 2023/0130025 A1
(43) Pub. Date: Apr. 27, 2023

(54) PHOTORESIST COMPOSITIONS AND METHODS FOR FABRICATING SEMICONDUCTOR DEVICE USING THE SAME

(71) Applicant: Samsung Electronics Co., Ltd., Suwon-si (KR)

(72) Inventors: Cha Won KOH, Yongin-si (KR); Tsunehiro NISHI, Suwon-si (KR); Ji Young PARK, Suwon-si (KR); Dong Il SHIN, Suwon-si (KR); Chang Soo WOO, Suwon-si (KR); Min Young LEE, Suwon-si (KR); Hyun Jae LEE, Hwaseong-si (KR)

(73) Assignee: Samsung SDI Co., Ltd., Yongin-si (KR)

(21) Appl. No.: 17/938,338

(22) Filed: Oct. 6, 2022

(30) Foreign Application Priority Data
Oct. 20, 2021 (KR) 10-2021-0140182

(51) Int. Cl. G03F 7/029; G03F 7/039; G03F 7/004; G03F 7/20

(52) U.S. Cl. CPC G03F 7/029; G03F 7/20; G03F 7/0041; G03F 7/0392

(57) ABSTRACT

A photoresist composition including an organometallic compound, and a method for fabricating a semiconductor device using the same are provided. The photoresist composition may include an organometallic compound, a radical sensitizer including a structure of Chemical formula 2-1 or Chemical formula 2-2, and a solvent.

In Chemical formula 2-1,

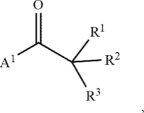

A¹ is a substituted or unsubstituted hydrocarbon group having 1 to 20 carbon atoms, and R¹, R² and R³ are each independently hydrogen, a halogen, a substituted or unsubstituted hydrocarbon group having 1 to 20 carbon atoms, or a hetero-functional group.

In Chemical formula 2-2,

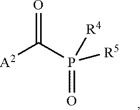

A² is a substituted or unsubstituted hydrocarbon group having 1 to 20 carbon atoms, and R⁴ and R⁵ are each independently hydrogen, a halogen, a substituted or unsubstituted hydrocarbon group having 1 to 20 carbon atoms, or a hetero-functional group.

### CROSS-REFERENCE TO RELATED APPLICATION

This application claims priority to Korean Patent Application No. 10-2021-0140182, filed on Oct. 20, 2021, and all the benefits accruing therefrom under 35 U.S.C. §119, the disclosure of which is incorporated herein by reference in its entirety.

### BACKGROUND

The present inventive concept relates to a photoresist composition and a method for fabricating a semiconductor device using the same. More specifically, the present inventive concept relates to an extreme ultraviolet (EUV) photoresist composition including an organometallic compound and a method for fabricating a semiconductor device using the same.

As the design rules of semiconductor devices are gradually reduced, various techniques for forming fine patterns have been developed. For example, an extreme ultraviolet lithography process that utilizes EUV light having a short wavelength as a light source may be used. In particular, in a mass production process of nano-class semiconductor devices of 40 nm or less, extreme ultraviolet having a wavelength of about 10 nm to about 14 nm may be used.

A chemically amplified photoresist, such as a polymeric photoresist, may be used to perform an EUV lithography process. However, the chemically amplified photoresist may have characteristics (e.g., resolution, photospeed or line edge roughness (LER)) that may deteriorate in a fine pattern.

In order to overcome such drawbacks of the chemically amplified photoresists, a new type of high-performance photoresist, an inorganic photoresist, is being studied. Since inorganic photoresists contain inorganic elements that have an extreme UV absorption rate higher than hydrocarbons, the inorganic photoresists may provide high sensitivity, even with a non-chemically amplified mechanism, and may provide excellent performance in terms of line edge roughness and defects.

### SUMMARY

Aspects of the present inventive concept provide a photoresist composition having improved sensitivity.

Aspects of the present inventive concept also provide a method for fabricating a semiconductor device having improved productivity, using the photoresist composition having improved sensitivity.

However, aspects of the present inventive concept are not limited to the one set forth herein. The above and other aspects of the present inventive concept will become more apparent to one of ordinary skill in the art to which the present inventive concept pertains by referencing the detailed description of the present inventive concept given below.

According to some embodiments of the present inventive concept, there is provided a photoresist composition comprising an organometallic compound, a radical sensitizer comprising a structure of Chemical formula 2-1 or Chemical formula 2-2, and a solvent. Wherein in Chemical formula 2-1

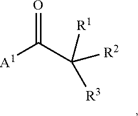

A¹ is a substituted or unsubstituted hydrocarbon group having 1 to 20 carbon atoms, and R¹, R² and R³ are each independently hydrogen, a halogen, a substituted or unsubstituted hydrocarbon group having 1 to 20 carbon atoms, or a hetero functional group. Wherein in Chemical formula 2-2

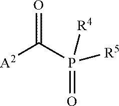

A² is a substituted or unsubstituted hydrocarbon group having 1 to 20 carbon atoms, and R⁴ and R⁵ are each independently hydrogen, a halogen, a substituted or unsubstituted hydrocarbon group having 1 to 20 carbon atoms, or a hetero functional group.

According to some embodiments of the present inventive concept, there is provided a photoresist composition comprising an organometallic compound including tin (Sn), a radical sensitizer comprising a structure of Chemical formula 2-1, and a solvent, wherein

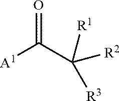

A¹ is a substituted or unsubstituted hydrocarbon group having 1 to 20 carbon atoms, and R¹, R² and R³ are each independently hydrogen, a halogen, a substituted or unsubstituted hydrocarbon group having 1 to 20 carbon atoms, or a hetero-functional group.

According to some embodiments of the present inventive concept, there is provided a method for fabricating a semiconductor device, the method comprising forming a target film on a substrate, forming a photoresist film on the target film, the photoresist film including an organometallic compound, a radical sensitizer comprising a structure of Chemical formula 2-1 or Chemical formula 2-2, and a solvent, performing an exposure process and a development process on the photoresist film to form a photoresist pattern, and patterning the target film, using the photoresist pattern as an etching mask. Wherein in Chemical formula 2-1

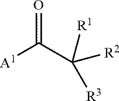

A¹ is a substituted or unsubstituted hydrocarbon group having 1 to 20 carbon atoms, and R¹, R² and R³ are each independently hydrogen, a halogen, a substituted or unsubstituted hydrocarbon group having 1 to 20 carbon atoms, or a hetero-functional group, and wherein in Chemical formula 2-2

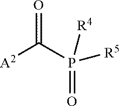

A² is a substituted or unsubstituted hydrocarbon group having 1 to 20 carbon atoms, and R⁴ and R⁵ are each independently hydrogen, a halogen, a substituted or unsubstituted hydrocarbon group having 1 to 20 carbon atoms, or a hetero-functional group.

### BRIEF DESCRIPTION OF DRAWINGS

The above and other aspects and features of the present inventive concept will become more apparent by describing in detail example embodiments thereof with reference to the attached drawings, in which:

FIGS. 1 to 5 are diagrams illustrating a method for fabricating a semiconductor device according to some embodiments of the present inventive concept.

### DETAILED DESCRIPTION

Hereinafter, photoresist compositions according to example embodiments will be described.

As used herein, the term “substituted” means that a hydrogen atom is substituted with deuterium, a halogen atom, a hydroxy group, a cyano group, a nitro group, an alkyl group, an amine group, an amino group, a silyl group, a thiol group, an aryl group, an alkoxy group, or a combination thereof. The term “unsubstituted” means that hydrogen atom is not substituted with another substituent and remains as a hydrogen atom.

As used herein, the term “hetero” means that heteroatoms (e.g., oxygen (O), nitrogen (N), sulfur (S), phosphorus (P), etc.) are present, and not only carbon (C) and hydrogen (H) are included in the functional group.

As used herein, the term “saturated aliphatic hydrocarbon group” refers to a hydrocarbon group in which bonds between carbon atoms in a molecule are single bonds, unless otherwise defined. As an example, the saturated aliphatic hydrocarbon group may be, but is not limited to, a methyl group, an ethyl group, a propyl group, an isopropyl group, an n-butyl group, an isobutyl group, a sec-butyl group, a 2,2-dimethylpropyl group or a tert-butyl group.

As used herein, the term “saturated alicyclic hydrocarbon group” refers to a hydrocarbon group including a ring in which bonds between carbon atoms in the molecule are single bonds. As an example, the saturated alicyclic hydrocarbon group may be, but is not limited to, a cyclopropyl group, a cyclobutyl group, a cyclopentyl group, or a cyclohexyl group.

As used herein, the term “unsaturated aliphatic hydrocarbon group” refers to a hydrocarbon group including at least one bond between carbon atoms that is a double bond or a triple bond. The hydrocarbon group may have one or more double bonds and/or one or more triple bonds. As an example, the unsaturated aliphatic hydrocarbon group may be, but is not limited to, a vinyl group, an ethynyl group, an allyl group, a 1-propenyl group, a 2-propenyl group, a 1-propynyl group, a 2-propynyl group, a 1-butenyl group, a 2-butenyl group, a 3-butenyl group, a 1-butenyl group, a 2-butynyl group or a 3-butynyl group.

As used herein, the term “unsaturated alicyclic hydrocarbon group” refers to a hydrocarbon group including a ring wherein at least one bond between carbon atoms is a double bond or a triple bond. The hydrocarbon group may have one or more double bonds and/or one or more triple bonds. As an example, the unsaturated alicyclic hydrocarbon group may be, but is not limited to, 1-cyclopropenyl group, 2-cyclopropenyl group, 1-cyclobutenyl group, 2-cyclobutenyl group, 1-cyclopentenyl group, 2-cyclopentenyl group, 3-cyclopentenyl group, a 1-cyclohexenyl group, a 2-cyclohexenyl group, or a 3-cyclohexenyl group.

As used herein, the term “aromatic hydrocarbon group” refers to a hydrocarbon group including an aromatic ring group in the molecule. As an example, the aromatic hydrocarbon group may be, but is not limited to, a phenyl group or a naphthalene group.

As used herein, the term “and/or” includes any and all combinations of one or more of the associated listed items.

The photoresist composition according to some embodiments of the present inventive concept may include an organometallic compound, a radical sensitizer, and a solvent.

The organometallic compound may be an organometallic monomer or an organometallic cluster. For example, the organometallic compound may include tin (Sn), antimony (Sb), zinc (Zn), zirconium (Zr), indium (In) and/or hafnium (Hf). In some embodiments, the organometallic compound may include tin (Sn). As an example, the organometallic compound may include a structure of Chemical formula 1.

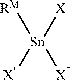

In Chemical formula 1, R^{M} may be a substituted or unsubstituted hydrocarbon group having 1 to 20 carbon atoms. For example, the R^{M} may include a substituted or unsubstituted saturated aliphatic hydrocarbon group having 1 to 20 carbon atoms, a substituted or unsubstituted saturated alicyclic hydrocarbon group having 3 to 10 carbon atoms, a substituted or unsubstituted unsaturated aliphatic hydrocarbon group having 2 to 20 carbon atoms, a substituted or unsubstituted unsaturated alicyclic hydrocarbon group having 3 to 10 carbon atoms, and/or a substituted or unsubstituted aromatic hydrocarbon group having 6 to 20 carbon atoms.

In the Chemical formula 1, each X, X′ and X″ may be a ligand that binds to a central metal atom (e.g., tin (Sn)). For example, X, X′ and X″ may independently include an oxygen (O) atom, a halogen, a hydroxy group, a cyano group, a nitro group, an alkyl group, an amine group, a silyl group, an aryl group, and/or an alkoxy group.

The content of the organometallic compound may be, for example, from about 0.1% by weight to about 99% by weight on the basis of the total weight of the photoresist composition. In some embodiments, the content of the organometallic compound may be from about 0.1% by weight to about 20% by weight on the basis of the total weight of the photoresist composition.

The organometallic compound in the photoresist composition may form cross-links when a metal radical (e.g., a tin radical (Sn radical)) is generated by a light source. The light source may be a KrF excimer laser light source, an ArF excimer laser light source, or extreme ultraviolet (EUV) light. In some embodiments, the light source may be extreme ultraviolet (EUV) light. As an example, the organometallic compound represented by the Chemical formula 1 may form cross-linking by an oxo bond by generating a tin radical as shown in Reaction formula 1 below by extreme ultraviolet.

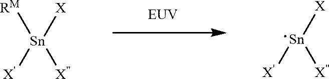

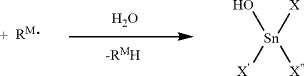

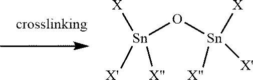

The radical sensitizer may be, for example, a ketone compound having 1 to 80 carbon atoms. As an example, the radical sensitizer may include a structure of Chemical formula 2.

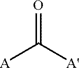

In some embodiments, in Chemical formula 2, A may be a substituted or unsubstituted hydrocarbon group having 1 to 20 carbon atoms. As an example, A may include a substituted or unsubstituted saturated aliphatic hydrocarbon group having 1 to 20 carbon atoms, a substituted or unsubstituted saturated alicyclic hydrocarbon group having 3 to 10 carbon atoms, a substituted or unsubstituted unsaturated aliphatic hydrocarbon group having 2 to 20 carbon atoms, a substituted or unsubstituted unsaturated alicyclic hydrocarbon group having 3 to 10 carbon atoms, and/or a substituted or unsubstituted aromatic hydrocarbon groups having 6 to 20 carbon atoms.

In some embodiments, in Chemical formula 2, A′ may be a substituted or unsubstituted hydrocarbon group having 1 to 60 carbon atoms. As an example, A′ may include a substituted or unsubstituted saturated aliphatic hydrocarbon group having 1 to 60 carbon atoms, a substituted or unsubstituted saturated alicyclic hydrocarbon group having 3 to 60 carbon atoms, a substituted or unsubstituted unsaturated aliphatic hydrocarbon group having 2 to 60 carbon atoms, a substituted or unsubstituted unsaturated alicyclic hydrocarbon group having 3 to 60 carbon atoms, and/or a substituted or unsubstituted aromatic hydrocarbon group having 6 to 60 carbon atoms.

The content of the radical sensitizer may be, for example, about 0.01% by weight to about 50% by weight based on the weight of the organometallic compound. In some embodiments, the content of the radical sensitizer may be from about 0.01% by weight to about 20% by weight based on the weight of the organometallic compound.

The radical sensitizer may generate organic radicals by interacting with the light source. As an example, the radical sensitizer including a structure of Chemical formula 2 may generate an organic radical (e.g., A′·) as in the following Reaction formula 2-1 through a Norrish reaction by extreme ultraviolet radiation.

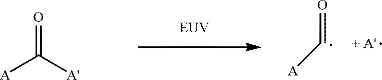

The organic radicals may induce a cross-linking reaction in the organometallic compound by generating a metal radical (e.g., a tin radical) from the organometallic compound. As an example, the organometallic radical (A′·) generated by Reaction formula 2-1 may induce cross-linking of the organometallic compound by an oxo bond by generating a tin radical as in Reaction formula 2-2 below.

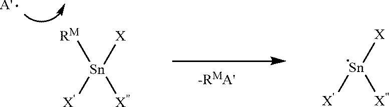

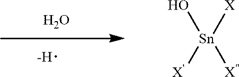

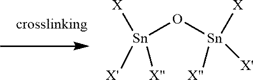

Therefore, the radical sensitizer may improve the sensitivity of the photoresist composition. Specifically, as described above, in the photoresist composition according to some embodiments, in addition to the metal radicals (e.g., tin radicals according to Reaction formula 1) from the light source (e.g., extreme ultraviolet), additional metal radicals (e.g., tin radicals according to the Reaction formula 2-2) by the radical sensitizer may be generated. Therefore, since the production efficiency of metal radicals is enhanced, it is possible to provide a photoresist composition having improved sensitivity.

In some embodiments, A of Chemical formula 2 may be a substituted or unsubstituted aromatic hydrocarbon group having 6 to 20 carbon atoms. As an example, A of Chemical formula 2 may be a substituted or unsubstituted phenyl group. In such a case, since the radical (e.g., A-C·=O) generated from the radical sensitizer may be relatively stable due to resonance stabilization, the organic radical may be easily generated by the light source (e.g., A′·).

In some embodiments, A′ of Chemical formula 2 may be a substituted or unsubstituted alkyl group having 1 to 60 carbon atoms. As an example, the radical sensitizer may include a structure of Chemical formula 2-1.

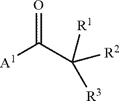

In Chemical formula 2-1, A¹ may be a substituted or unsubstituted hydrocarbon group having 1 to 20 carbon atoms. In Chemical formula 2-1, R¹, R² and R³ may each independently be hydrogen, a halogen, a substituted or unsubstituted hydrocarbon group having 1 to 20 carbon atoms, or a hetero-functional group containing a hetero element (e.g., oxygen (O), nitrogen (N), sulfur (S) or phosphorus (P)). As an example, R¹, R² and R³ may each independently include hydrogen, a halogen, a substituted or unsubstituted saturated aliphatic hydrocarbon group having 1 to 20 carbon atoms, a substituted or unsubstituted saturated alicyclic hydrocarbon group having 3 to 10 carbon atoms, a substituted or unsubstituted unsaturated aliphatic hydrocarbon group having 2 to 20 carbon atoms, a substituted or unsubstituted unsaturated alicyclic hydrocarbon group having 3 to 10 carbon atoms, a substituted or unsubstituted aromatic hydrocarbon group having 6 to 20 carbon atoms, a hydroxy group, an amine group, and/or a thiol group.

In some embodiments, at least one of R¹, R² and R³ may be a hydroxy group, a substituted or unsubstituted alkoxy group, or a substituted or unsubstituted phenyl group. In such a case, since the radical (e.g., C·-R¹R²R³) generated from the radical sensitizer may be relatively stable due to resonance stabilization, the organic radical (e.g., A′·) may be easily generated by the light source.

In some embodiments, A′ of Chemical formula 2 may be a substituted or unsubstituted secondary alkyl group having 3 to 40 carbon atoms, or a substituted or unsubstituted tertiary alkyl group having 4 to 60 carbon atoms. For example, in Chemical formula 2-1, R¹ and R² may each independently be a substituted or unsubstituted hydrocarbon group having 1 to 20 carbon atoms, and R³ may be hydrogen or a substituted or unsubstituted hydrocarbon group having 1 to 20 carbon atoms. In such a case, since the radical (e.g., C·- R¹R²R³) generated from the radical sensitizer may be relatively stable due to an EDG (electron donating group), the organic radical (e.g., A′·) may be easily generated by the light source.

As an example, the radical sensitizer may include one or more of the following compounds:

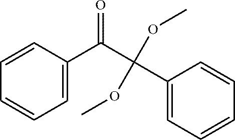 [SMILES: COC(OC)(C(=O)c1ccccc1)c1ccccc1]

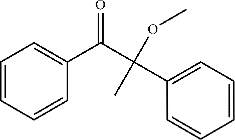 [SMILES: COC(C)(C(=O)c1ccccc1)c1ccccc1]

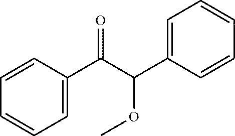 [SMILES: COC(C(=O)c1ccccc1)c1ccccc1]

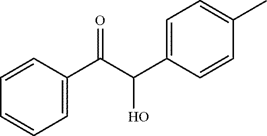 [SMILES: Cc1ccc(C(O)C(=O)c2ccccc2)cc1]

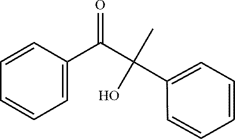 [SMILES: CC(O)(C(=O)c1ccccc1)c1ccccc1]

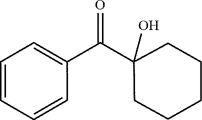 [SMILES: O=C(c1ccccc1)C1(O)CCCCC1]

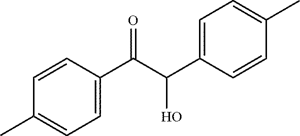

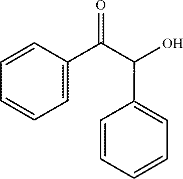 [SMILES: O=C(c1ccccc1)C(O)c1ccccc1]

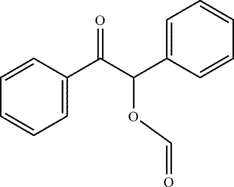 [SMILES: O=COC(C(=O)c1ccccc1)c1ccccc1]

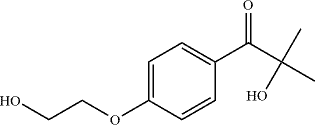 [SMILES: CC(C)(O)C(=O)c1ccc(OCCO)cc1]

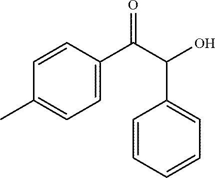 [SMILES: Cc1ccc(C(=O)C(O)c2ccccc2)cc1]

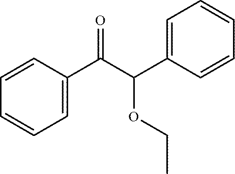 [SMILES: CCOC(C(=O)c1ccccc1)c1ccccc1]

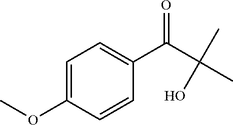

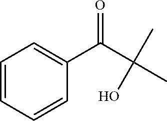

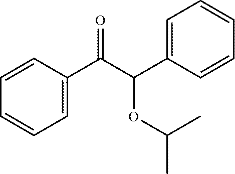 [SMILES: CC(C)OC(C(=O)c1ccccc1)c1ccccc1]

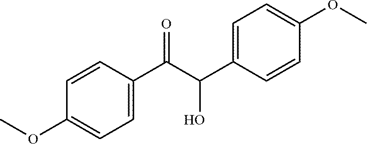

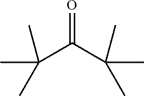

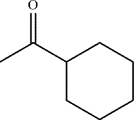

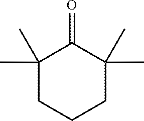

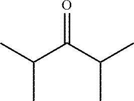

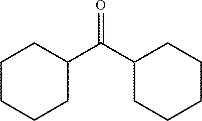 [SMILES: O=C(C1CCCCC1)C1CCCCC1]

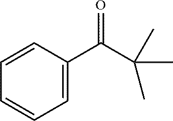

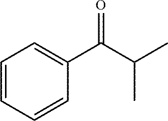

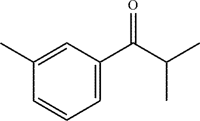

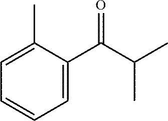

In some embodiments, A′ of Chemical formula 2 may be a substituted or unsubstituted methyl group or a substituted or unsubstituted primary alkyl group having 1 to 20 carbon atoms. For example, in Chemical formula 2-1, R¹ may be hydrogen or a substituted or unsubstituted hydrocarbon group having 1 to 20 carbon atoms, and each of R² and R³ may be hydrogen.

As an example, the radical sensitizer may include one or more of the following compounds:

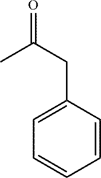

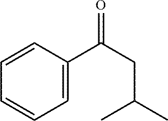

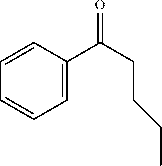

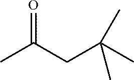

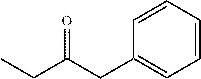

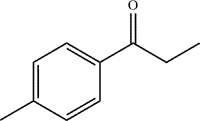

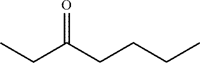

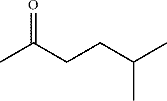

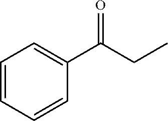

In some embodiments, when A′ of Chemical formula 2 is a substituted or unsubstituted methyl group, A of Chemical formula 2 may be a substituted or unsubstituted aromatic hydrocarbon group having 6 to 20 carbon atoms. As an example, A of Chemical formula 2 may be a substituted or unsubstituted phenyl group. In such a case, since the radical (e.g., AC·=O) generated from the radical sensitizer may be relatively stable by the resonance stabilization, the organic radical (e.g., A′·) may be easily generated by the light source.

As an example, the radical sensitizer may include one or more of the following compounds:

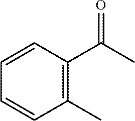

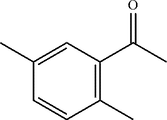

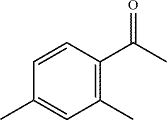

The radical sensitizer may easily generate an organic radical (e.g., A′· of the Reaction formula 2-1) by a light source (e.g., extreme ultraviolet light), the generated organic radical may easily generate the metal radical (e.g., the tin radicals of the Reaction formula 2-2) from the organic metal compound, and by-products produced during the process (e.g., R^{M}A' of the Reaction formula 2-2) may be selected from materials that form a stable structure. In addition, the radical sensitizer may be selected from non-volatile materials by having an appropriately large molecular weight.

As an example, the radical sensitizers may include one or more of the following compounds 2,2-Dimethoxy-1,2-diphenylethanone, 2-Hydroxy-2-methyl-1-pheynylpropan-1-one, 2,2,4,4-Tetramethyl-3-pentanone, Dicyclohexyl ketone, 2,2-Dimethylpropiophenone, Isobutyrophenone, Valerophenone, 3-Heptanone, 5-Methyl-2-hexanone, 1-Phenyl-1-propanone, or the compounds below:

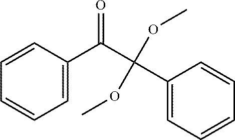 [SMILES: COC(OC)(C(=O)c1ccccc1)c1ccccc1]

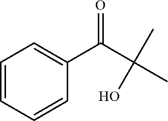

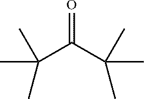

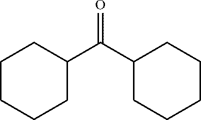 [SMILES: O=C(C1CCCCC1)C1CCCCC1]

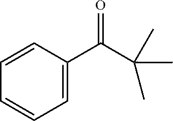

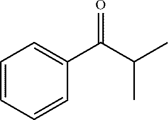

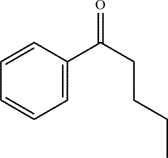

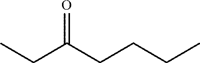

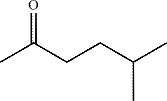

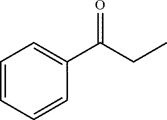

In some other embodiments, A′ of Chemical formula 2 may be a substituted or unsubstituted phosphine oxide group. As an example, the radical sensitizer may include a structure of Chemical formula 2-2.

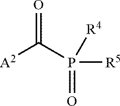

In Chemical formula 2-2, A² may be a substituted or unsubstituted hydrocarbon group having 1 to 20 carbon atoms. In Chemical formula 2-2, R⁴ and R⁵ may each independently be hydrogen, a halogen, a substituted or unsubstituted hydrocarbon group having 1 to 20 carbon atoms, or a hetero-functional group containing hetero element (e.g., oxygen (O), nitrogen (N), sulfur (S) or phosphorus (P)). As an example, R⁴ and R⁵ may each independently include hydrogen, a halogen, a substituted or unsubstituted saturated aliphatic hydrocarbon group having 1 to 20 carbon atoms, a substituted or unsubstituted saturated alicyclic hydrocarbon group having 3 to 10 carbon atoms, a substituted or unsubstituted unsaturated aliphatic hydrocarbon group having 2 to 20 carbon atoms, a substituted or unsubstituted unsaturated alicyclic hydrocarbon group having 3 to 10 carbon atoms, a substituted or unsubstituted aromatic hydrocarbon group having 6 to 20 carbon atoms, a hydroxy group, an amine group, and/or a thiol group.

In some embodiments, at least one of R⁴ and R⁵ may be a substituted or unsubstituted aromatic hydrocarbon group having 6 to 20 carbon atoms. As an example, at least one of R⁴ and R⁵ may be a substituted or unsubstituted phenyl group. In this case, since the radical (e.g., O=P·-R⁴R⁵) generated from the radical sensitizer may be relatively stable by the resonance stabilization, the organic radical (e.g., A′·) may be easily generated by the light source.

In some embodiments, the radical sensitizer may include the following compound (Diphenyl (2,4,6-trimethylbenzoyl) phosphine oxide):

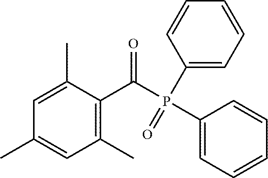 [SMILES: Cc1cc(C)c(C(=O)P(=O)(c2ccccc2)c2ccccc2)c(C)c1]

The solvent may be an organic solvent. As an example, the solvent may include, but is not limited to, aromatic compounds (e.g., xylene, toluene), alcohols (e.g., 4-methyl-2-pentanol, 4-methyl-2-propanol, 1-butanol, methanol, isopropyl alcohol, and 1-propanol), ethers (e.g., anisole, and tetrahydrofuran), ester compounds (n-butyl acetate, propylene glycol monomethyl ether acetate, ethyl acetate, and ethyl lactate), and/or ketones (e.g., methyl ethyl ketone, and 2-heptanone).

In some embodiments, the photoresist composition may further include one or more of a binder resin, a photo-polymerizable monomer, a photopolymerization initiator, and a surfactant, or the like, in addition to the organic metal compound, the radical sensitizer and the solvent.

The binder resin may include, for example, an acrylic binder resin. The acrylic binder resin is a copolymer of a first ethylenically unsaturated monomer and a second ethylenically unsaturated monomer that is copolymerizable with the first ethylenically unsaturated monomer and may be a resin that includes one or more acrylic-based repeating units.

The first ethylenically unsaturated monomer is an ethylenically unsaturated monomer containing one or more carboxyl groups and may include, for example, but is not limited to, acrylic acid, methacrylic acid, maleic acid, itaconic acid, and/or fumaric acid.

The second ethylenically unsaturated monomer may include, for example, but is not limited to, aromatic vinyl compounds such as styrene, α-methylstyrene, vinyltoluene and vinylbenzylmethyl ether; unsaturated carboxylic acid ester compounds such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, and phenyl(meta)crylate; unsaturated carboxylic acid aminoalkyl ester compounds such as 2-aminoethyl(meth)acrylate and 2-dimethylaminoethyl(meth)acrylate; carboxylic acid vinyl ester compounds such as vinyl acetate and vinyl benzoate; unsaturated carboxylic acid glycidyl ester compounds such as glycidyl(meth)acrylate; vinyl cyanide compounds such as (meta)acrylonitrile; and/or unsaturated amide compounds such as (meth)acrylamide.

As an example, the acrylic binder resin may include, but is not limited to, polybenzyl methacrylate, (meth)acrylic acid/benzyl methacrylate copolymer, (meth)acrylic acid/benzyl methacrylate/styrene copolymer, (meth)acrylic acid/benzyl methacrylate/2-hydroxyethyl methacrylate copolymer, and/or (meth)acrylic acid/benzyl methacrylate/styrene/2-hydroxyethyl methacrylate copolymer.

The content of the binder resin may be, for example, about 1% by weight to about 20% by weight (e.g., about 3% by weight to 15% by weight) on the basis of the total weight of the photoresist composition. When the content of the binder resin is as described above, excellent sensitivity, residual film ratio, developability, resolution and straightness of the pattern may be obtained.

The photo-polymerizable monomer may include, for example, a mono-functional or multi-functional ester of (meth)acrylic acid including at least one ethylenically unsaturated double bond. Since the photo-polymerizable monomer has the ethylenically unsaturated double bond, it may induce sufficient polymerization at the time of exposure in the pattern forming process. Accordingly, it is possible to form a pattern having excellent heat resistance, light resistance, and chemical resistance.

As an example, the photo-polymerizable monomer may include, but is not limited to, ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaelythritol tetra(meth)acrylate, pentaerythritol hexa(meth)acrylate, dipentaerythritol di(meth)acrylate, dipentaerythritol tri(meth)acrylate, dipentaerythritol penta (meth)acrylate, dipentaerythritol hexa(meth)acrylate, bisphenol A epoxy (meth)acrylate, ethylene glycol monomethyl ether(meta)acrylate, trimethylol propane tri(meta)acrylate, tris(meta) acryloyloxyethyl phosphate, and/or novolak epoxy(meta)acrylate. The photo-polymerizable monomer may also be used by being treated with an acid anhydride to impart better developability.

The content of the photo-polymerizable monomer may be, for example, about 1% by weight to 20% by weight (e.g., about 1% by weight to about 15% by weight) on the basis of the total weight of the photoresist composition. When the content of the photo-polymerizable monomer is as described above, since sufficient curing may occur at the time of exposure in the pattern forming process, excellent reliability may be obtained, and the pattern may have, for example, excellent heat resistance, light resistance, chemical resistance, resolution and adhesion.

The photopolymerization initiator may be an initiator generally used in a photoresist composition and may include, for example, but is not limited to, an acetophenone-based compound, a benzophenone-based compound, a thioxanthone-based compound, a benzoin-based compound, a triazine-based compound, an oxime-based compound, an aminoketone-based compound, or a combination thereof. Alternatively, the photopolymerization initiator may include a carbazole-based compound, a diketone compound, a sulfonium borate-based compound, a diazo-based compound, an imidazole-based compound, and/or a biimidazole-based compound.

As an example, the photopolymerization initiator may include, but is not limited to, tetraethylene glycol bis-3-mercapto propionate, pentaerythritol tetrakis-3-mercapto propionate, and/or dipentaerythritol tetrakis-3-mercapto propionate.

The content of the photopolymerization initiator may be, for example, about 0.1% by weight to 5% by weight (e.g., about 0.3% by weight to about 3% by weight) on the basis of the total weight of the photoresist composition. When the content of the photopolymerization initiator is as described above, since curing may sufficiently occur at the time of exposure in the pattern forming process, excellent reliability may be obtained, the heat resistance, light resistance, chemical resistance, resolution, and adhesion of the pattern may be excellent, and it may be possible to prevent a decrease in transmittance due to unreacted initiator.

The surfactant may reduce or prevent deterioration of the coating properties of the photoresist composition due to the high organometallic compound content. The surfactant may include, for example, but is not limited to, alkylbenzene sulfonates, alkylpyridinium salts, polyethylene glycol, and/or quaternary ammonium salts.

In some embodiments, the photoresist composition may further include an additive to reduce or prevent staining or spotting when coating, leveling properties, or generation of residues due to unphenomenon. The additive may include, for example, but is not limited to, malonic acid or 3-amino-1,2-propanediol, a leveling agent, and/or a radical polymerization initiator. The content of the additive may be easily adjusted depending on the desired physical properties.

In some embodiments, the photoresist composition may further include an adhesive force enhancer for improving the strength of the adhesive bond with the substrate. For example, a silane coupling agent may be used as the adhesive force enhancer. The silane coupling agent may include, for example, but is not limited to, carbon-carbon unsaturated bond-containing silane compounds such as vinyltrimethoxysilane, vinyltriethoxysilane, vinyltrichlorosilane, vinyltris (β-methoxyethoxy)silane; or 3-methacryloxypropyltrimethoxysilane, 3-acrylicoxypropyltrimethoxysilane, p-styryltrimethoxysilane, 3-methacryloxypropylmethyldimethoxysilane, 3-methacryloxypropylmethyldiethoxysilane; and/or trimethoxy[3-(phenylamino)propyl]silane.

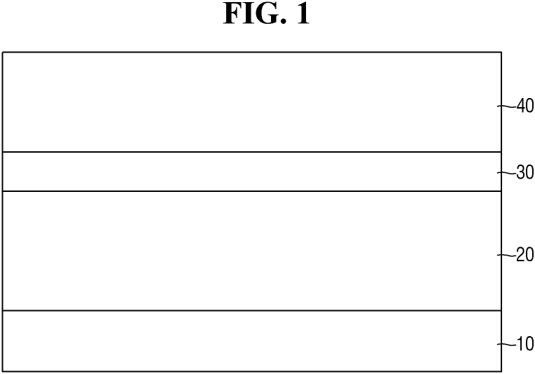

Hereinafter, a method of fabricating a semiconductor device according to example embodiments will be described referring to FIGS. 1 to 5.

FIGS. 1 to 5 are diagrams illustrating a method for fabricating a semiconductor device according to some embodiments of the present inventive concept.

Referring to FIG. 1, a target film 20, a mask film 30, and a photoresist film 40 are sequentially formed on a substrate 10.

The substrate 10 may be bulk silicon or silicon-on-insulator (SOI). The substrate 10 may be a silicon substrate or may include other materials, for example, silicon germanium, gallium arsenide, silicon germanium on insulator (SGOI), indium antimonide, lead tellurium compounds, indium arsenide, indium phosphide, gallium arsenide, and/or gallium antimonide. In some embodiments, the substrate 10 may have an epi-layer formed on a base substrate, or may be a ceramic substrate, a quartz substrate, a glass substrate for a display, or the like.

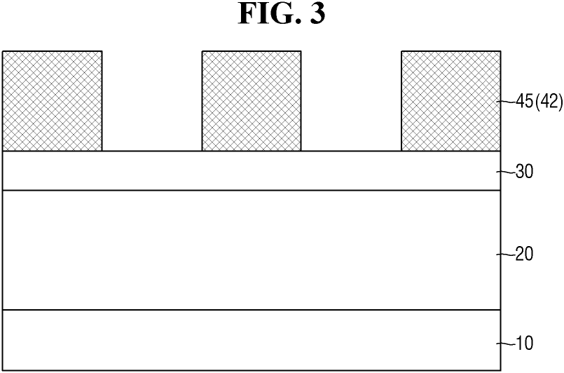

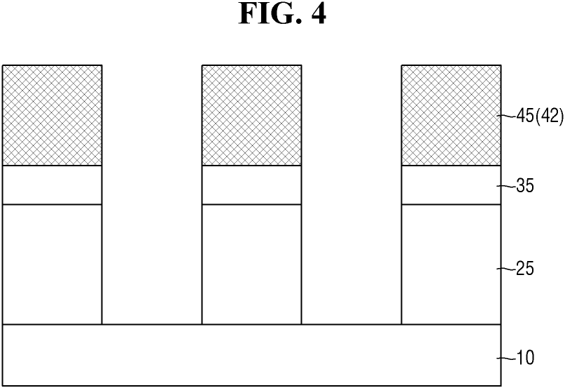

The target film 20 may be formed on the substrate 10. The target film 20 may be a layer in which an image is transferred from a photoresist pattern (e.g., a photoresist pattern 45 of FIG. 3) to be described later and converted into a predetermined target pattern (e.g., a target pattern 25 of FIG. 4).

In some embodiments, the target film 20 may include a conductive material such as metal, metal nitride, metal silicide, and/or metal silicide nitride film. In some embodiments, the target film 20 may include insulating materials such as silicon oxide, silicon nitride, and/or silicon oxynitride. In some embodiments, the target film 20 may include a semiconductor material such as polysilicon.

The mask film 30 may be formed on the target film 20. The mask film 30 may be formed by, for example, being applied onto the target film 20 by a spin coating process and then performing a baking process. The mask film 30 may include, for example, but is not limited to, a spin-on hard mask (SOH).

The photoresist film 40 may be formed on the mask film 30. The photoresist film 40 may be formed on the mask film 30 by, for example, an application process such as a spin coating process, a dip coating process, and a spray coating process. In some embodiments, the photoresist film 40 may be applied onto the mask film 30 and then a pre-curing process such as a soft-baking process may be performed.

The photoresist film 40 may include the photoresist composition. For example, the photoresist film 40 may include the organometallic compound, the radical sensitizer, and the solvent.

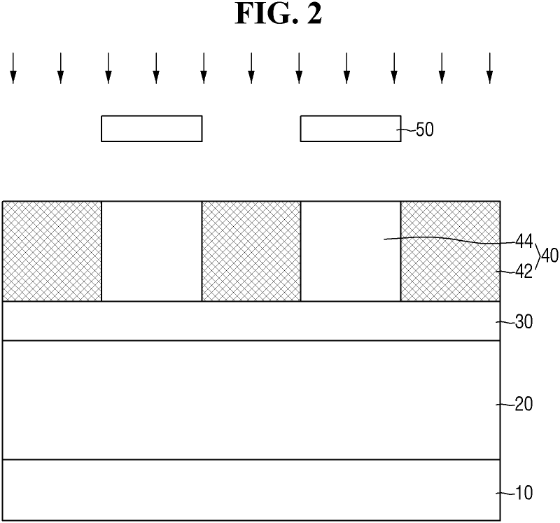

Referring to FIG. 2, the exposure process of the photoresist film 40 is performed.

The photoresist film 40 may be divided into an exposed portion 42 and a non-exposed portion 44 by the exposure process. For example, the exposure mask 50 may be placed on the photoresist film 40. When light is emitted from the upper part of the exposure mask 50 through a light source, the light that has passed through the transmission portion of the exposure mask 50 may be applied to a part of the photoresist film 40 to form the exposed portion 42. The other part of the photoresist film 40 that was not irradiated with light by a shielding portion of the exposure mask 50 may form the non-exposed portion 44. The light source may be a KrF excimer laser light source, an ArF excimer laser light source, or extreme ultraviolet (EUV) light. In some embodiments, the light source may be extreme ultraviolet (EUV) light.

The organometallic compound of the exposed portion 42 may form cross-linking, for example, due to an oxo bond by light (e.g., extreme ultraviolet light) as in Reaction formula 1 and Reaction formula 2-2. Accordingly, the exposed portion 42 may be cured by performing the exposure process.

Referring to FIG. 3, a development process is performed to form a photoresist pattern 45.

The photoresist pattern 45 may be formed by a negative tone development (NTD) process. For example, the cured exposed portion 42 may be left in the development process to form the photoresist pattern 45, and the non-exposed portion 44 may be dissolved and removed by the developer used in the development process. The developer may include, for example, but is not limited to, ketones such as methyl ethyl ketone, acetone, 2-heptanone, and cyclohexanone; alcohols such as 4-methyl-2-propanol, 1-butanol, isopropanol, 1-propanol and methanol; esters such as propylene glycol monomethyl ester acetate, ethyl acetate, ethyl lactate, n-butyl acetate, and butyrolactone; and/or aromatic compounds such as benzene, xylene and toluene.

Although the development process is explained as only a negative tone development (NTD) process, the present inventive concept is not limited thereto, and the development process may be a positive tone development (PTD) process. For example, as a developer, a quaternary ammonium hydroxide compound such as tetraethylammonium hydroxide, tetrapropylammonium hydroxide, and/or tetrabutylammonium hydroxide may be used.

In some embodiments, after the photoresist pattern 45 is formed, a curing process such as a hard baking process may be performed.

Referring to FIG. 4, the photoresist pattern 45 is used as an etching mask to pattern the target film 20.

For example, the mask pattern 35 and the target pattern 25 may be formed by performing an etching process on the mask film 30 and the target film 20, using the photoresist pattern 45 as an etching mask. The etching process may include a dry etching process and/or a wet etching process, depending on the substance constituting the target film 20, etching selectivity between the photoresist pattern 45 and the target film 20, and the like.

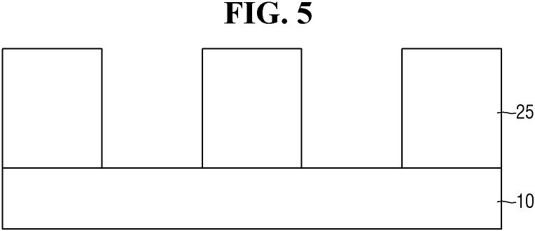

Referring to FIG. 5, the mask pattern 35 and the photoresist pattern 45 are removed.

The mask pattern 35 and the photoresist pattern 45 may be removed, for example, by an ashing process and/or a strip process.

As a result, the target pattern 25 may be formed on the substrate 10. When the target film 20 includes a conductive material, the target pattern 25 may form a predetermined conductive pattern. When the target film 20 includes the insulating material, the target pattern 25 may form a predetermined insulating pattern. When the target film 20 includes the semiconductor material, the target pattern 25 may form a predetermined semiconductor pattern.

Hereinafter, the effect of the photoresist composition according to example embodiments will be described referring to the following test examples and the following comparative examples.

### Test Example 1

The photoresist composition was produced, using an organotin copolymer including a structural unit represented by the following Chemical formula 1-1 and the following Chemical formula 1-2 as the organometallic compound, using 2,2-Dimethoxy-1,2-diphenylethanone as the radical sensitizer, and using MIBC (Methyl Isobutyl Carbinol) as the solvent. In the following Chemical formula 1-1 and the following Chemical formula 1-2, * represents a bonding site.

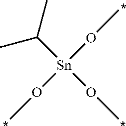

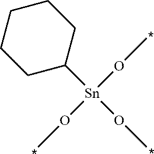

Specifically, the coating solution was produced by dissolving 1.5% by weight of the organotin copolymer and 0.15% by weight of 2,2-Dimethoxy-1,2-diphenylethanone in MIBC (Methyl Isobutyl Carbinol) and stirring them for 1 day or more, and a photoresist composition was produced by filtering it through a 0.1 µm syringe filter.

### Comparative Example 1

A photoresist composition was produced in the manner similar to Test example 1, except that a radical sensitizer was not used.

### Evaluation

The photoresist compositions produced according to Test example 1 and Comparative example 1 were spin-coated on a thin film deposition substrate at 1,500 rpm for 30 seconds and fired at 100° C. for 120 seconds to form the photoresist film. As the thin film deposition substrate, a circular silicon wafer having a diameter of 4 inches having a native-oxide surface was used. As a result of measuring the photoresist film through an ellipsometry method, the thickness was 25 nm and the uniformity was 0.9 nm.

Next, the photoresist film formed according to Test example 1 and Comparative example 1 was exposed to extreme ultraviolet light to form a line/space pattern of 16 nm to 100 nm, while changing the energy and focus. After the exposure, the mixture was fired at 180° C. for 120 seconds, immersed in a Petri dish containing 2-heptanone for 60 seconds, taken out, and then rinsed with the same solvent for 10 seconds. Next, after firing at 150° C. for 5 minutes, a pattern image was obtained using an SEM (scanning electron microscope). An optimum light intensity (dose) and depth of focus (DOF) checked from the SEM image are evaluated and provided in Table 1 below.

TABLE 1

| | dose (mJ/cm²) | DOF (nm) |
|---|---|---|
| Test example 1 | 64.1 | 80 |
| Comparative Example 1 | 66.8 | 80 |

Referring to Table 1, it is shown that the photoresist film produced according to Test example 1 can form a required pattern even with reduced light intensity, by containing the radical sensitizer, as compared with Comparative example 1, which does not use the radical sensitizer. Therefore, the photoresist composition according to some embodiments may provide a method for fabricating a semiconductor device having improved productivity by having improved sensitivity.

While the present inventive concept has been particularly shown and described with reference to some example embodiments thereof, it will be understood by those of ordinary skill in the art that various changes in form and details may be made therein without departing from the scope of the present inventive concept as defined by the following claims. It is therefore desired that example embodiments be considered in all respects as illustrative and not restrictive, reference being made to the appended claims rather than the foregoing description to indicate the scope of the invention.

1. A photoresist composition comprising:
an organometallic compound;
a radical sensitizer comprising a structure of Chemical formula 2-1 or Chemical formula 2-2; and
a solvent,
wherein in Chemical formula 2-1 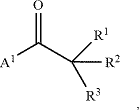
A¹ is a substituted or unsubstituted hydrocarbon group having 1 to 20 carbon atoms, and
R¹, R² and R³ are each independently hydrogen, a halogen, a substituted or unsubstituted hydrocarbon group having 1 to 20 carbon atoms, or a hetero-functional group, and
wherein in Chemical formula 2-2 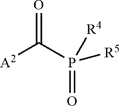
A² is a substituted or unsubstituted hydrocarbon group having 1 to 20 carbon atoms, and
R⁴ and R⁵ are each independently hydrogen, a halogen, a substituted or unsubstituted hydrocarbon group having 1 to 20 carbon atoms, or a hetero-functional group.

2. The photoresist composition of claim 1, wherein the organometallic compound includes tin (Sn), antimony (Sb), zinc (Zn), zirconium (Zr), indium (In) and/or hafnium (Hf).

3. The photoresist composition of claim 1, wherein the radical sensitizer is configured to generate an organic radical by a Norrish reaction, and
the organic radical is configured to induce a cross-linking reaction in the organometallic compound.

4. The photoresist composition of claim 1, wherein A¹ is a substituted or unsubstituted aromatic hydrocarbon group having 6 to 20 carbon atoms.

5. The photoresist composition of claim 4, wherein A¹ is a substituted or unsubstituted phenyl group.

6. The photoresist composition of claim 1, wherein at least one of R¹, R² and R³ is a hydroxy group, a substituted or unsubstituted alkoxy group, or a substituted or unsubstituted phenyl group.

7. The photoresist composition of claim 1, wherein R¹ and R² are each independently a substituted or unsubstituted hydrocarbon group having 1 to 20 carbon atoms.

8. The photoresist composition of claim 1, wherein each of R² and R³ is hydrogen.

9. The photoresist composition of claim 8, wherein R¹ is a substituted or unsubstituted aliphatic hydrocarbon group having 1 to 20 carbon atoms.

10. The photoresist composition of claim 8, wherein A¹ is a substituted or unsubstituted aromatic hydrocarbon group having 6 to 20 carbon atoms.

11. The photoresist composition of claim 1, wherein the radical sensitizer comprising a structure of Chemical formula 2-1 includes 2,2-Dimethoxy-1,2-diphenylethanone, 2-Hydroxy-2-methyl-1-pheynylpropan-1-one, 2,2,4,4-Tetramethyl-3-pentanone, Dicyclohexyl ketone, 2,2-Dimethylpropiophenone, Isobutyrophenone, Valerophenone, 3-Heptanone, 5-Methyl-2-hexanone and/or 1-Phenyl-1-propanone.

12. The photoresist composition of claim 1, wherein at least one of R⁴ and R⁵ is a substituted or unsubstituted aromatic hydrocarbon group having 6 to 20 carbon atoms.

13. The photoresist composition of claim 12, wherein the radical sensitizer comprising a structure of Chemical formula 2-2 includes Diphenyl(2,4,6-trimethylbenzoyl)phosphine oxide.

14. The photoresist composition of claim 1, wherein the radical sensitizer is present in the photoresist composition in an amount from 0.01% to 20% by weight on the basis of the organometallic compound.

15. A photoresist composition comprising:
an organometallic compound including tin (Sn);
a radical sensitizer comprising a structure of Chemical formula 2-1; and
a solvent,
wherein 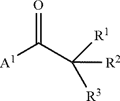
A¹ is a substituted or unsubstituted hydrocarbon group having 1 to 20 carbon atoms, and
R¹, R² and R³ are each independently hydrogen, a halogen, a substituted or unsubstituted hydrocarbon group having 1 to 20 carbon atoms, or a hetero-functional group.

16. The photoresist composition of claim 15, wherein the organometallic compound comprises a structure of Chemical formula 1: 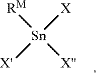
wherein R^{M} is a substituted or unsubstituted hydrocarbon group having 1 to 20 carbon atoms, and
each X, X′ and X″ is a ligand that binds to tin (Sn).

17. The photoresist composition of claim 15, wherein A is a substituted or unsubstituted aromatic hydrocarbon group having 6 to 20 carbon atoms.

18. The photoresist composition of claim 15, wherein at least one of R¹, R² and R³ is a hydroxy group, a substituted or unsubstituted alkoxy group, or a substituted or unsubstituted phenyl group.

19. The photoresist composition of claim 15, wherein R¹ and R² are each independently a substituted or unsubstituted hydrocarbon group having 1 to 20 carbon atoms.

20. (canceled)

21. A method for fabricating a semiconductor device, the method comprising:
forming a target film on a substrate;
forming a photoresist film on the target film, the photoresist film including an organometallic compound, a radical sensitizer comprising a structure of Chemical formula 2-1 or Chemical formula 2-2 and a solvent;
performing an exposure process and a development process on the photoresist film to form a photoresist pattern; and
patterning the target film, using the photoresist pattern as an etching mask,
wherein in Chemical formula 2-1 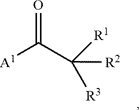
A¹ is a substituted or unsubstituted hydrocarbon group having 1 to 20 carbon atoms, and
R¹, R² and R³ are each independently hydrogen, a halogen, a substituted or unsubstituted hydrocarbon group having 1 to 20 carbon atoms, or a hetero-functional group, and
wherein in Chemical formula 2-2 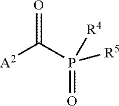
A² is a substituted or unsubstituted hydrocarbon group having 1 to 20 carbon atoms, and
R⁴ and R⁵ are each independently hydrogen, a halogen, a substituted or unsubstituted hydrocarbon group having 1 to 20 carbon atoms, or a hetero-functional group.

22-24. (canceled)
